(19) United States
(12) Patent Application Publication
(10) Pub. No.: US 2026/0304703 A1
(43) Pub. Date: Oct. 1, 2026

(54) HEAT DISSIPATION ASSEMBLY AND TERMINAL DEVICE

(71) Applicants: CHAMP TECH OPTICAL (FOSHAN) CORPORATION, Foshan (CN); FOXCONN TECHNOLOGY CO., LTD., New Taipei (TW)

(72) Inventors: Hai-Bin CHEN, Foshan (CN); Jun YAN, Foshan (CN); Di-Qiong ZHAO, Foshan (CN); Yung-Ping LIN, New Taipei (TW)

(21) Appl. No.: 19/322,970

(22) Filed: Sep. 9, 2025

(30) Foreign Application Priority Data
Apr. 1, 2025 (CN) 202520605411.7

(51) Int. Cl. H05K 7/20; G01K 1/14

(52) U.S. Cl. CPC H05K 7/2039; G01K 1/14; H05K 7/20336; H05K 7/208

(57) ABSTRACT

A heat dissipation assembly includes a base plate, a cover plate, a temperature sensor, and an encapsulating layer. The base plate defines a groove and a through hole communicating with the groove. The cover plate is disposed in the groove and the through hole. The cover plate and the base plate cooperatively form an accommodating groove. The accommodating groove includes a first accommodating area and a second accommodating area. The temperature sensor includes a main body, a bending portion, and a probe. The bending portion is connected to the main body and the probe. The main body is disposed in the first accommodating area, the bending portion is disposed in the second accommodating area, and the probe is disposed in the through hole. The encapsulating layer is filled in the accommodating groove and fix to the temperature sensor. The present disclosure further provides a terminal device.

### CROSS-REFERENCE TO RELATED APPLICATIONS

The present application claims the benefit and priority to Chinese Patent Application Serial No. 202520605411.7, filed on Apr. 1, 2025, and the content of which is hereby fully incorporated by reference into the present application.

### FIELD

The subject matter herein generally relates to heat dissipation technologies, and more particularly, to a heat dissipation assembly and a terminal device.

### BACKGROUND

A heat dissipation assembly may include a base plate and a temperature sensor disposed in the base plate. A heat generation element may be mounted on the base plate, such that the heat generated by the heat generation element can be dissipated by the heat dissipation assembly.

However, there is a certain distance between a probe of the temperature sensor and the heat generation element. Thus, the temperature sensing becomes inaccurate. Therefore, there is a room for improvement in the art.

### SUMMARY

Other aspects and embodiments of the present disclosure are also expected. The above summary and the following detailed description are not intended to limit the present disclosure to any particular embodiment, but are merely intended to describe some embodiments of the present disclosure.

A heat dissipation assembly includes a base, a cover plate, a temperature sensor, and an encapsulating layer. The base plate defines a groove and a through hole, the through hole communicating with the groove. The cover plate is disposed in the groove and the through hole, the cover plate and the base plate cooperatively form an accommodating groove. The accommodating groove includes a first accommodating area and a second accommodating area, and the second accommodating area communicates with the first accommodating area and the through hole. The temperature sensor includes a main body, a bending portion, and a probe. The bending portion is connected to the main body and the probe. The main body is disposed in the first accommodating area. The bending portion is disposed in the second accommodating area, and the probe is disposed in the through hole. The encapsulating layer is filled in the accommodating groove and fix to the temperature sensor.

In some embodiments, the base plate comprises a first surface, a second surface, and a side surface, the first surface and the second surface are opposite to each other, the side surface is connected to the first surface and the second surface; the groove is defined at the first surface and the side surface, the through hole extends through the second surface, and the probe is exposed from the second surface.

In some embodiments, the heat dissipation assembly further comprises a heat sink disposed on the first surface.

In some embodiments, the heat sink comprises a plurality of heat dissipating fins and a plurality of heat pipes, the first surface defines a mounting groove, a portion of each of the plurality of heat pipes is disposed in the mounting groove, and another portion of each of the plurality of heat pipe is disposed in the plurality of heat dissipating fins.

In some embodiments, the cover plate comprises a main body and a protruding portion, the protruding portion protrudes from the main body, the main body is disposed in the first accommodating area, and the protruding portion is disposed in the second accommodating area.

In some embodiments, a surface of the cover plate and the first surface coplanar.

In some embodiments, a cross-section of the second accommodating area comprises an arc.

In some embodiments, the encapsulating layer is made of epoxy resin.

In some embodiments, the base plate and the cover plate are made of metal.

A terminal device includes the heat dissipation assembly.

The step of fixing the temperature sensor in the base plate and the cover plate is performed before the step of welding the base plate and the cover plate, which is equivalent to performing the step of fixing the temperature sensor after the welding step, preventing damage to the temperature sensor at high temperatures during welding. The temperature sensor is disposed between the base plate and the cover plate, and a connection between the base plate and the cover plate has high reliability, thereby reducing the risk of the temperature sensor separating from the base plate and the cover plate. The probe of the temperature sensor is exposed from the base plate, thereby improving temperature sensing accuracy. Additionally, the second surface of the base plate is the appearance surface of the heat dissipation assembly, viewing from the side of the second surface, a relatively small through hole is defined at the second surface, which is beneficial for the aesthetics of the heat dissipation assembly, minimizes damage to the second surface, has minimal impact on the contact area between the second surface and the working element, and reduces the impact on the performance of the heat dissipation assembly.

### BRIEF DESCRIPTION OF THE DRAWINGS

Implementations of the present technology will now be described, by way of example only, with reference to the attached figures.

FIG. 1 is a diagrammatic view of a terminal device according to an embodiment of the present disclosure.

FIG. 2 is diagrammatic view of a heat dissipation assembly according to another embodiment of the present disclosure.

FIG. 3 is an exploded view illustrating a heat dissipation assembly of the terminal device in FIG. 1.

FIG. 4 is a diagrammatic view of a portion of the heat dissipation assembly shown in FIG. 1.

FIG. 5 is a cross-sectional view along A-A shown in FIG. 4.

FIG. 6 is a diagrammatic view showing an assembly process of the heat dissipation assembly shown in FIG. 1.

FIG. 7 is similar to FIG. 4, but showing a server viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If there is no conflict, the following embodiments and features in the embodiments can be combined with each other.

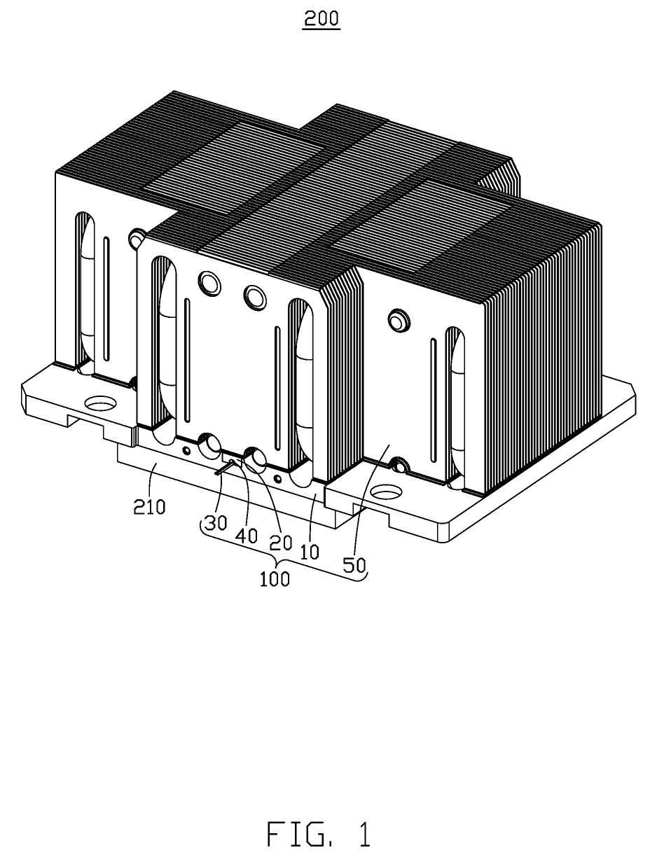

Referring to FIG. 1, a terminal device 200 is provided according to an embodiment of the present disclosure. The terminal device 200 includes a heat dissipation assembly 100 and a working element 210 disposed on the heat dissipation assembly 100. The working element 210 generates heat during operation, and the heat dissipation assembly 100 dissipates the heat to allow the working element 210 to operate at a suitable temperature. The terminal device 200 may be a server, a desktop computer, a laptop, etc.

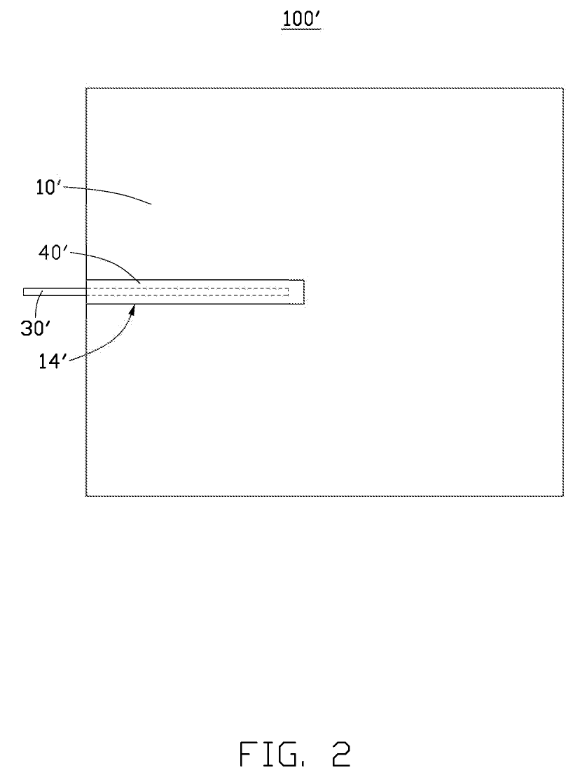

FIG. 2 is a diagrammatic view of a heat dissipation assembly 100’ according to another embodiment of the present disclosure. The heat dissipation assembly 100’ includes a base plate 10’, a temperature sensor 30’, and an encapsulating layer 40’. A groove 14’ is defined at a surface of the base plate 10’. The temperature sensor 30’ is disposed in the groove 14’. The encapsulating layer 40’ is disposed in the groove 14’ and covers the temperature sensor 30’. A probe of the temperature sensor 30’ for sensing temperature is embedded in the encapsulating layer 40’, which makes the temperature sensing inaccurate. Since the temperature sensor 30’ is fixed in the groove 14’ only by the encapsulating layer 40’, the temperature sensor 30’ may easily be separated from the groove 14’. When observed from the surface of the base plate 10’ having the groove 14’, there is a color difference between the base plate 10’ and the encapsulating layer 40’, resulting in a poor appearance of the heat dissipation assembly 100’.

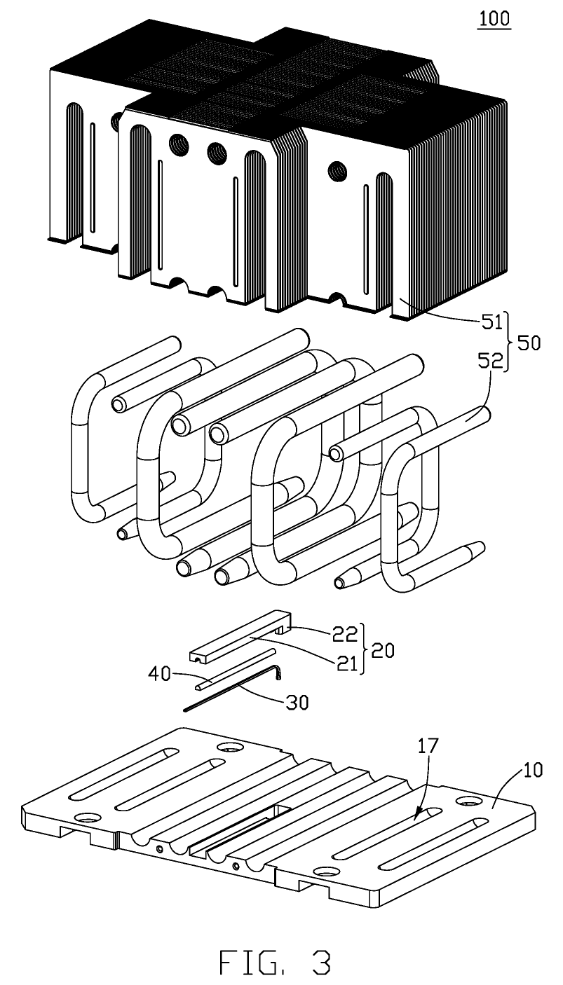

FIG. 3 is an exploded view of the heat dissipation assembly 100 shown in FIG. 1. The heat dissipation assembly 100 may include a base plate 10, a cover plate 20, a temperature sensor 30, an encapsulating layer 40, and a heat sink 50. The temperature sensor 30 and the encapsulating layer 40 are both disposed between the base plate 10 and the cover plate 20. The encapsulating layer 40 can fix the temperature sensor 30, and the heat dissipation assembly 100 is fixed to the base plate 10. The temperature sensing accuracy of the heat dissipation assembly 100 is high, the installation stability of the temperature sensor 30 is improved, and the appearance performance can also be enhanced.

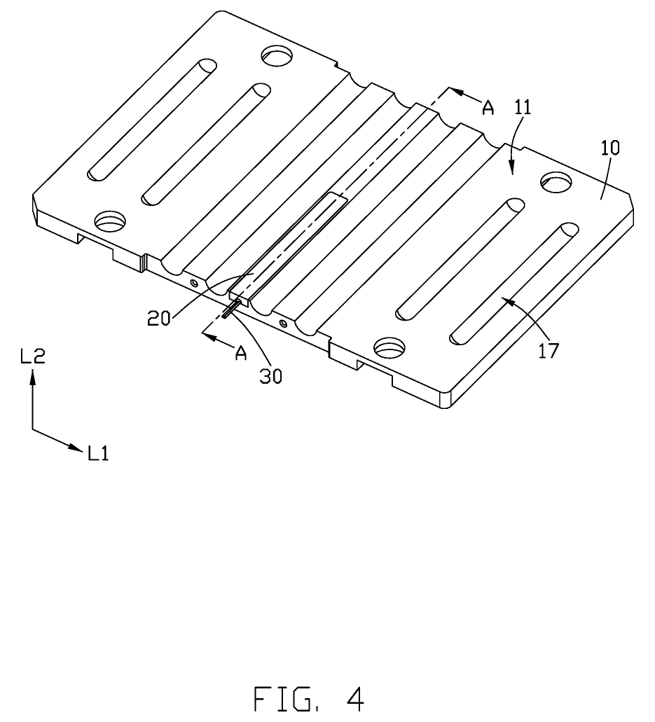

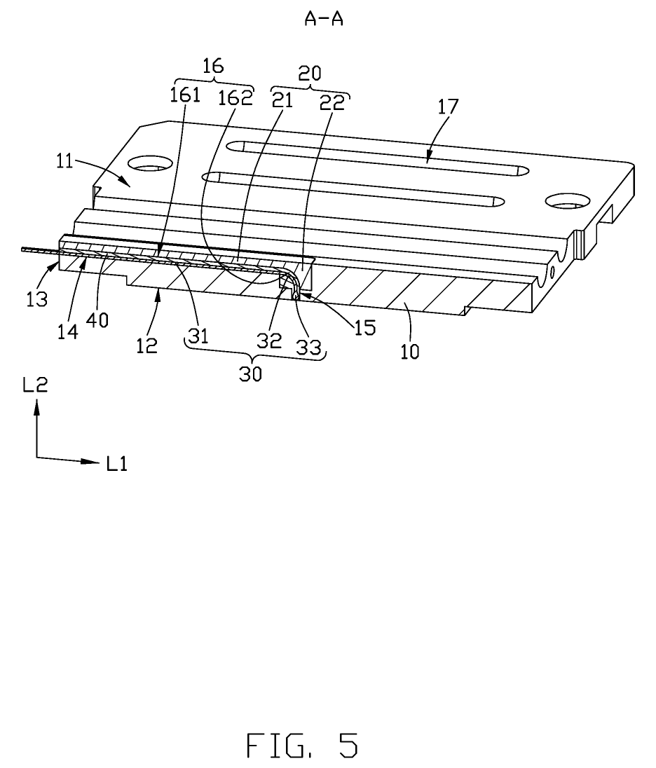

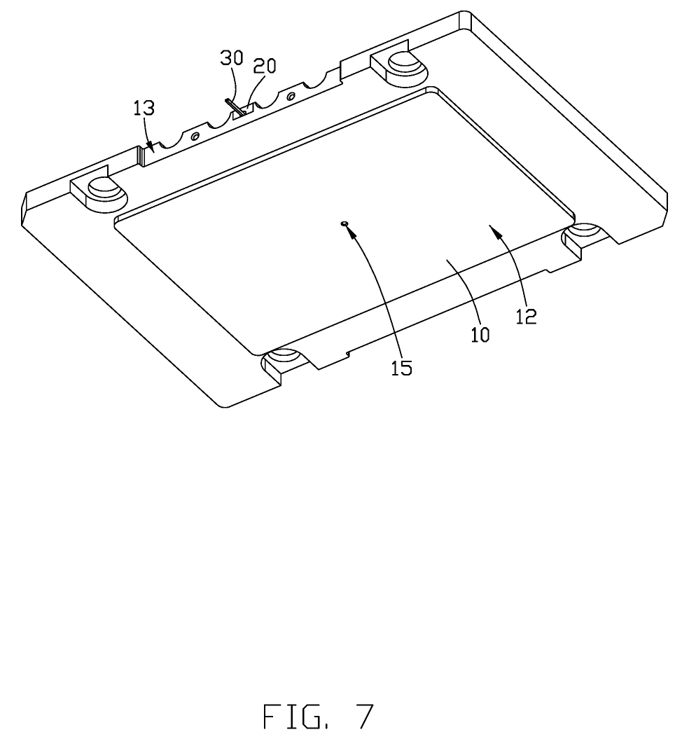

Referring to FIGS. 4 to 7, the base plate 10 is substantially plate-shaped. The base plate 10 may include a first surface 11, a second surface 12, and a side surface 13. The first surface 11 and the second surface 12 are opposite to each other. The side surface 13 is connected to the first surface 11 and the second surface 12.

A groove 14 and a through hole 15 are defined on the base plate 10. The through hole 15 communicates with the groove 14. The groove 14 is defined at the first surface 11 and the side surface 13. The through hole 15 extends through the second surface 12. Specifically, the groove 14 is substantially disposed along a first direction L1. The through hole 15 extends through the first surface 11 and the second surface 12 along a second direction L2, wherein the first direction L1 intersects with the second direction L2. In the embodiment, the first direction L1 is perpendicular to the second direction L2.

The cover plate 20 may include a main body 21 and a protruding portion 22, and the main body 21 is substantially strip-shaped. The protruding portion 22 is located on the main body 21. The main body 21 and the protruding portion 22 are integrally formed. The cover plate 20 is disposed in the groove 14.

The cover plate 20 and the base plate 10 cooperatively form an accommodating groove 16. The accommodating groove 16 can accommodate the temperature sensor 30 and the encapsulating layer 40. The accommodating groove 16 may include a first accommodating area 161 and a second accommodating area 162 communicating with each other. The second accommodating area 162 communicates with both the first accommodating area 161 and the through hole 15. Each of the first accommodating area 161 and the second accommodating area 162 are a portion of the groove 14.

The temperature sensor 30 may include a main body 31, a bending portion 32, and a probe 33. The bending portion 32 is connected to the main body 31 and the probe 33. The main body 31 is disposed in the first accommodating area 161. The bending portion 32 is disposed in the second accommodating area 162. The probe 33 is disposed in the through hole 15. The heat sink 50 is disposed on the first surface 11. The probe 33 is exposed from the second surface 12. The working element 210 is disposed on the second surface 12. The probe 33 can sense the temperature at the second surface 12 of the heat dissipation assembly 100.

The heat sink 50 may include heat dissipating fins 51 and a heat pipe assembly 52. The heat pipe assembly 52 includes a plurality of heat pipes 521. The heat dissipating fins 51 are mounted on the first surface 11. One end of each heat pipe 521 is connected to the base plate 10, and another end of each heat pipe 521 is connected to the heat dissipating fins 51. Specifically, each heat pipe 521 is bent-shaped. A mounting groove 17 is defined at the first surface 11, a portion of the heat pipes 521 is disposed in the mounting groove 17, which can increase a contact area between the heat pipes 521 and the base plate 10, thereby facilitating the heat transformation. The heat pipes 521 being accommodated in the mounting groove 17 can also reduce a thickness of the heat dissipation assembly 100 along the second direction L2. Another portion of the heat pipes 521 is disposed in the heat dissipating fins 51, thereby facilitating a rapid heat dissipation through the heat dissipating fins 51.

The encapsulating layer 40 can be made of an insulating material, such as epoxy resin. The encapsulating layer 40 is filled in the accommodating groove 16.

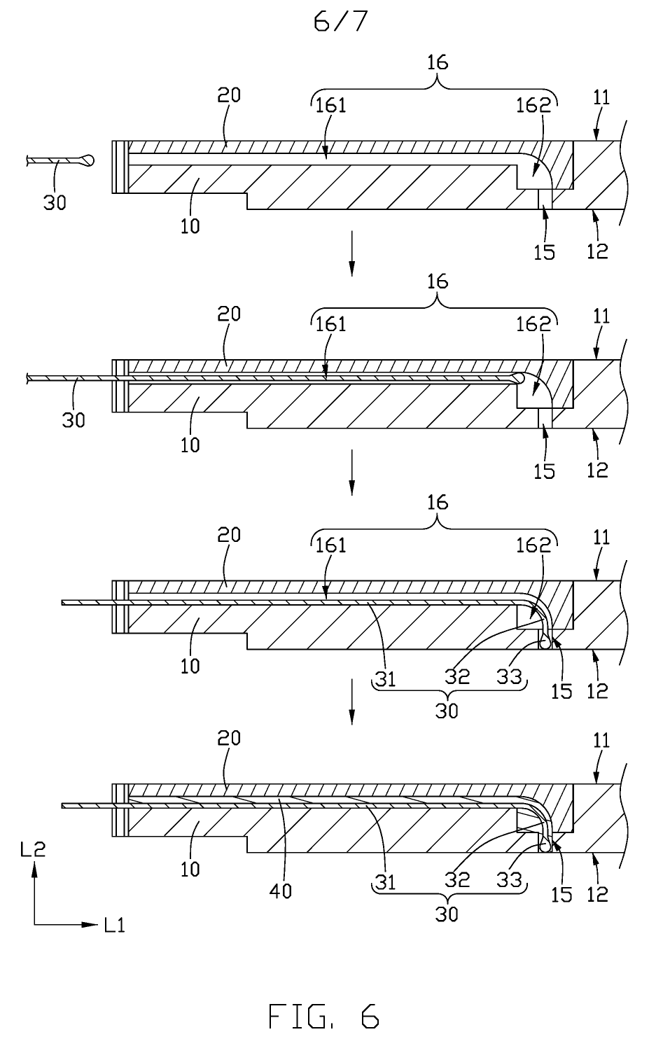

Referring to FIG. 6, during the assembling of the heat dissipation assembly 100, the cover plate 20 may be first placed in the base plate 10. The cover plate 20 and the base plate 10 are fixed to each other to form the accommodating groove 16. The cover plate 20 and the base plate 10 may be fixed by welding. The probe 33 of the temperature sensor 30 is inserted into the accommodating groove 16 from the first accommodating area 161. During the inserting of the temperature sensor 30, the bending portion 32 of the temperature sensor 30 bends in the second accommodating area 162, and the probe 33 is finally disposed in the through hole 15 and exposed from the base plate 10. After injecting and curing the encapsulating layer 40 in the accommodating groove 16, the encapsulating layer 40 fills the first accommodating area 161 and the second accommodating area 162, and the encapsulating layer 40 can fix the temperature sensor 30 to the cover plate 20 and the base plate 10. The heat sink 50 is fixed to the base plate 10, and the heat sink 50 may be detachably fixed using nuts.

In the embodiment, the step of fixing the temperature sensor 30 in the base plate 10 and the cover plate 20 is performed before the step of welding the base plate 10 and the cover plate 20, which is equivalent to performing the step of fixing the temperature sensor 30 after the welding step, preventing damage to the temperature sensor 30 at high temperatures during welding. The temperature sensor 30 is disposed between the base plate 10 and the cover plate 20, and a connection between the base plate 10 and the cover plate 20 has high reliability, thereby reducing the risk of the temperature sensor 30 separating from the base plate 10 and the cover plate 20. The probe 33 of the temperature sensor 30 is exposed from the base plate 10, thereby improving temperature sensing accuracy. Additionally, the second surface 12 of the base plate 10 is the appearance surface of the heat dissipation assembly 100, viewing from the side of the second surface 12, a relatively small through hole 15 is defined at the second surface 12, which is beneficial for the aesthetics of the heat dissipation assembly 100, minimizes damage to the second surface 12, has minimal impact on the contact area between the second surface 12 and the working element 210, and reduces the impact on the performance of the heat dissipation assembly 100.

In some embodiments, the surface of the cover plate 20 facing away from the base plate 10 and the first surface 11 coplanar, which facilitates the assembly of the heat sink 50.

In some embodiments, along a direction perpendicular to both the first direction L1 and the second direction L2, a cross-section of the second accommodating area 162 is arc, which facilitates the bending of the temperature sensor 30 in the second accommodating area 162 during the step of inserting the temperature sensor 30 into the accommodating groove 16, thereby facilitates the assembly of the temperature sensor 30.

The base plate 10 and the cover plate 20 are both made of metal. The metal has rapid heat conduction and can improve the strength of the heat dissipation assembly 100.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat dissipation assembly comprising:
a base plate defining a groove and a through hole, the through hole communicating with the groove;
a cover plate disposed in the groove and the through hole, the cover plate and the base plate cooperatively forming an accommodating groove, the accommodating groove comprising a first accommodating area and a second accommodating area, and the second accommodating area communicating with the first accommodating area and the through hole;
a temperature sensor comprising a main body, a bending portion, and a probe, the bending portion connected to the main body and the probe, the main body disposed in the first accommodating area, the bending portion disposed in the second accommodating area, and the probe disposed in the through hole; and
an encapsulating layer filled in the accommodating groove and fix to the temperature sensor.

2. The heat dissipation assembly of claim 1, wherein the base plate comprises a first surface, a second surface, and a side surface, the first surface and the second surface are opposite to each other, the side surface is connected to the first surface and the second surface; the groove is defined at the first surface and the side surface, the through hole extends through the second surface, and the probe is exposed from the second surface.

3. The heat dissipation assembly of claim 2, wherein the heat dissipation assembly further comprises a heat sink disposed on the first surface.

4. The heat dissipation assembly of claim 3, wherein the heat sink comprises a plurality of heat dissipating fins and a plurality of heat pipes, the first surface defines a mounting groove, a portion of each of the plurality of heat pipes is disposed in the mounting groove, and another portion of each of the plurality of heat pipe is disposed in the plurality of heat dissipating fins.

5. The heat dissipation assembly of claim 2, wherein the cover plate comprises a main body and a protruding portion, the protruding portion protrudes from the main body, the main body is disposed in the first accommodating area, and the protruding portion is disposed in the second accommodating area.

6. The heat dissipation assembly of claim 2, wherein a surface of the cover plate and the first surface coplanar.

7. The heat dissipation assembly of claim 1, wherein a cross-section of the second accommodating area comprises an arc.

8. The heat dissipation assembly of claim 1, wherein the encapsulating layer is made of epoxy resin.

9. The heat dissipation assembly of claim 1, wherein the base plate and the cover plate are made of metal.

10. A terminal device comprising:
a working element; and
a heat dissipation assembly comprising:
a base plate defining a groove and a through hole, the through hole communicating with the groove, the working element disposed on the base plate;
a cover plate disposed in the groove and the through hole, the cover plate and the base plate cooperatively forming an accommodating groove, the accommodating groove comprising a first accommodating area and a second accommodating area, and the second accommodating area communicating with the first accommodating area and the through hole;
a temperature sensor comprising a main body, a bending portion, and a probe, the bending portion connected to the main body and the probe, the main body disposed in the first accommodating area, the bending portion disposed in the second accommodating area, and the probe disposed in the through hole; and
an encapsulating layer filled in the accommodating groove and fix to the temperature sensor.

11. The terminal device of claim 1, wherein the base plate comprises a first surface, a second surface, and a side surface, the first surface and the second surface are opposite to each other, the side surface is connected to the first surface and the second surface; the groove is defined at the first surface and the side surface, the through hole extends through the second surface, and the probe is exposed from the second surface, the working element is disposed on the second surface.

12. The terminal device of claim 11, wherein the heat dissipation assembly further comprises a heat sink disposed on the first surface.

13. The terminal device of claim 12, wherein the heat sink comprises a plurality of heat dissipating fins and a plurality of heat pipes, the first surface defines a mounting groove, a portion of each of the plurality of heat pipes is disposed in the mounting groove, and another portion of each of the plurality of heat pipe is disposed in the plurality of heat dissipating fins.

14. The terminal device of claim 11, wherein the cover plate comprises a main body and a protruding portion, the protruding portion protrudes from the main body, the main body is disposed in the first accommodating area, and the protruding portion is disposed in the second accommodating area.

15. The terminal device of claim 11, wherein a surface of the cover plate and the first surface coplanar.

16. The terminal device of claim 10, wherein a cross-section of the second accommodating area comprises an arc.

17. The terminal device of claim 10, wherein the encapsulating layer is made of epoxy resin.

18. The terminal device of claim 10, wherein the base plate and the cover plate are made of metal.
